(19) United States
(12) Patent Application Publication
(10) Pub. No.: US 2026/0072082 A1
(43) Pub. Date: Mar. 12, 2026

(54) DEVICE INTERFACE AND METHOD OF ADJUSTING THE SAME

(71) Applicant: ADVANTEST CORPORATION, Tokyo (JP)

(72) Inventors: Haokun Zhang, Tokyo (JP); Gang Zhao, Tokyo (JP)

(21) Appl. No.: 19/285,762

(22) Filed: Jul. 30, 2025

(30) Foreign Application Priority Data
Sep. 10, 2024 (CN) 202411261914.3

(51) Int. Cl. G01R 31/319

(52) U.S. Cl. CPC G01R 31/31905

(57) ABSTRACT

A device interface disposed between a test head and a device under test is disclosed. The device interface includes a first adjusting set, a second adjusting set, two first frames, two second frames, and electrical connection parts. The two first frames are disposed in parallel on the first adjusting set, and move toward or away from each other along the Y-axis direction for bearing the performance board. The two second frames are disposed in parallel on the second adjusting set, and move toward or away from each other along the Y-axis direction for corresponding to the probe module of the test head. One end of the electrical connection part is mounted on the first frame to be electrically connected to the performance board, and the other end of the electrical connection part is mounted on the second frame to be electrically connected to the probe module.

### FIELD OF THE INVENTION

The present relates to a test device for semiconductor devices, and more particularly to a device interface between a test head and a device under test, and a method of adjusting the same.

### BACKGROUND OF THE INVENTION

Typically, a test device for semiconductor devices includes a test head, and a performance boards or loadboard on the test head. Chip test sockets of devices under test are carried on the performance board and therefore signals output from the test head are transmitted to the chips under test through the chip test sockets.

To fit the test heads with various sizes, a corresponding performance board is required for compatibly assembling with the test head, thereby lowering a flexibility of the performance boards. In addition, when using a large-area performance board, if the chip test sockets mounted on the performance board cannot be stably supported or held, the test quality of the device under test (DUT) may be compromised.

### SUMMARY OF THE INVENTION

The present invention provides a device interface and a method of adjusting the same to improve the flexibility for the test head and performance board and to support various sizes of chip test sockets on the performance board.

To achieve one, some, or all of the above-mentioned objectives, or other objectives, the present invention provides a device interface disposed between a test head and a device under test. The test head includes probe modules. The device under test includes a performance board and chip test sockets. The device interface includes a first adjusting set, a second adjusting set, two first frames, two second frames, and electrical connection parts. The two first frames are disposed in parallel on the first adjusting set. The two first frames are adapted to move toward or away from each other along a Y-axis direction through an actuation of the at least one first adjusting set. A spacing is located between the two first frames. The two first frames are adapted to bear the performance board. The two second frames are disposed in parallel on the second adjusting set. The two second frames are adapted to move toward or away from each other along the Y-axis direction through an actuation of the second adjusting set. The two second frames are adapted to correspond to the probe modules of the test head. Each of the electrical connection parts includes one end installed in one of the two first frames and electrically connected to the performance board, and the other end installed in one of the two second frames and electrically connected to the probe module.

In an embodiment of the present invention, the first adjusting set includes two first gear rack and a first pinion. The he two first gear racks are parallel to each other in their length direction and extend along the Y-axis direction. The first pinion is engaged between the first gear racks. The first gear racks are adapted to move correspondingly on two opposite sides of a radial direction of the first pinion. One of the two first frames is disposed on one of the first gear racks, and the other first frame is disposed on the other first gear rack.

In an embodiment of the present invention, the first adjusting set further includes two first rails and a plurality of first sliding docks. The first rails are disposed parallel to the first gear racks. The first sling docks are disposed on two opposite ends of the two first frames and mounted on the first rails. When the two first frames are actuated along the first gear racks, the first sliding docks slide on the first rails, respectively.

In an embodiment of the present invention, a quantity of the first adjusting set are two. The two first adjusting sets are disposed separately. The two first frames are disposed in parallel on the two first adjusting sets. The first pinions of the two first adjusting sets are rotated synchronously.

In an embodiment of the present invention, the second adjusting set includes two second gear racks and a second pinion. The two second gear racks are parallel to each other in their length direction and extend along the Y-axis direction. The second pinion is engaged between the second gear racks. The second gear racks are adapted to move correspondingly on opposite sides of a radial direction of the second pinion. One of the two second frames is disposed on one of the two second gear racks, and the other second frame is disposed on the other second gear rack.

In an embodiment of the present invention, the second adjusting set further includes two second rails and a plurality of second sliding docks. The second rails are disposed parallel to the second gear racks. The second sliding docks are disposed on two opposite ends of the two second frames and mounted on the second rails. When the two second frames are actuated along with the second gear racks, the second sliding docks slide on the second rails, respectively.

In an embodiment of the present invention, a quantity of the second adjusting set is two, and the two second adjusting sets are disposed separately. The two second frames are disposed in parallel on the two second adjusting sets. The second pinions of the two second adjusting sets are rotated synchronously.

In an embodiment of the present invention, a rotation direction of the first pinion is opposite to or the same as that of the second pinion.

In an embodiment of the present invention, the device interface further includes a base. The first adjusting set further includes a first motor and the second adjusting set further includes a second motor. The base includes two first sidewalls opposite to each other. The first motor and the second motor are disposed on the first sidewalls. A drive shaft of the first motor is connected to the first pion for controlling the first pinion's actuation, and a drive shaft of the second motor is connected to the second pinion for controlling the second pinion's actuation.

In an embodiment of the present invention, the device interface further includes a base and two retractable dust protection caps. The base includes two second sidewalls opposite to each other. Each of the retractable dust protection caps is connected between each of the two first frames and each of the second sidewalls. The retractable dust protection caps are elongated when the two first frames move toward each other along the Y-axis direction, and the retractable dust protection caps are compressed when the two second frames move away from each other along the Y-axis direction.

In an embodiment of the present invention, the device interface further includes a third adjusting set, a fourth adjusting set, and a bearing structure disposed in the spacing. The bearing structure includes first support bars, second support bars, and support pillars. The first support bars are arranged along an X-axis direction on the third adjusting set. The first support bars includes odd-sequenced first support bars and even-sequenced first support bars. Through an actuation of the third adjusting set, a moving direction of the odd-sequenced first support bars along the X-axis direction is opposite to a moving direction of the even-sequenced first support bars along the X-axis direction. The second support bars are arranged across the first support bars. The second support bars are disposed along the Y-axis direction in the fourth adjusting set. The second support bars include odd-sequenced second support bars and even-sequenced second support bars. Through an actuation of the fourth adjusting set, a moving direction of the odd-sequenced second support bars along the Y-axis direction is opposite to a moving direction of the even-sequenced second support bars along the Y-axis direction. The support pillars are placed through locations where the first support bars and the second support bars cross each other.

In an embodiment of the present invention, at the locations where the first support bars and the second support bars cross each other, each of the first support bars has a first groove along a length direction of the first support bar and each of the second support bars has a second groove along a length direction of the second support bar. The first grooves and the second grooves form a cross shape in the intersection. Each of the support pillars is disposed at one of the locations where the first grooves and the second grooves overlap.

In an embodiment of the present invention, when the odd-sequenced first support bars and the even-sequenced first support bars move along the X-axis direction, the support pillars slide along the second grooves. When the odd-sequenced second support bars and the even-sequenced second support bars move along the Y-axis direction, the support pillars slide along the first grooves.

In an embodiment of the present invention, viewing along one of the second support bars, the support pillars includes the first support pillar to the 2m-th support pillar arranged sequentially along the X-axis direction, where m is a positive integer. A distance between the (2n-1)-th support pillar and the 2n-th support pillar corresponds to a length of each chip testing socket in the X-axis direction, where n is a positive integer and n is less than or equal to m.

In an embodiment of the present invention, viewing along one of the first support bars, the support pillars include the first support pillar to the 2p-th support pillar arranged sequentially along the Y-axis direction, where p is a positive integer. A distance between the (2q-1)-th support pillar and the 2q-th support pillar corresponds to a width of each chip testing socket in the Y-axis direction, where q is a positive integer and q is less than or equal to p.

In an embodiment of the present invention, the device interface further includes support bases. Each of the support bases includes a main body and a plurality of protruding platform sections. The main body includes a first surface and a second surface opposite to each other. The protruding platform sections are formed on the first surface. Each of the support bases is jointly supported by the (2q-1)-th support pillars and the 2q-th support pillars which are disposed on the two adjacent first support bars and distributed at the four corners of the support base, or by the (2n-1)-th support pillars and the 2n-th support pillars which are disposed on the two adjacent second support bars and distributed at the four corners of the support base.

In an embodiment of the present invention, each of the support pillars includes a slot. Each of the support bases includes four insert sections which are inserted into the slots of the support pillars at the four corners of the support base.

In an embodiment of the present invention, the third adjusting set includes two third gear racks and a third pinion. The third gear racks are parallel to each other in the length direction and extend along the X-axis direction. The third pinion is engaged between the third gear racks. The third gear racks are adapted to move correspondingly on two opposite sides of a radial direction of the third pinion. The odd-sequenced first support bars are fixed on one of the third gear racks, and the even-sequenced first support bars are fixed on the other of the third gear racks.

In an embodiment of the present invention, each of the third gear racks includes a plurality of first install holes arranged along the length direction. Each of the first support bars is fixedly installed in one of the first install holes.

In an embodiment of the present invention, a quantity of the third adjusting set is two. The two third adjusting sets are disposed separately. The third pinions of the two third adjusting sets are rotated synchronously. The odd-sequenced first support bars are fixed on the two third gear racks of the two third adjusting sets which move in the same direction. The even-sequenced first support bars are fixed on the other two third gear racks of the two third adjusting sets which move in the same direction.

In an embodiment of the present invention, the fourth adjusting set includes two fourth gear racks and a fourth pinion. The two fourth gear racks are parallel to each other in the length direction and extend along the Y-axis direction. The fourth pinion is engaged between the two fourth gear racks. The fourth gear racks are adapted to move correspondingly on two opposite sides of a radial direction of the fourth pinion. The odd-sequenced second support bars are fixed on one of the fourth gear racks, and the even-sequenced second support bars are fixed on the other of the fourth gear racks.

In an embodiment of the present invention, each of the fourth gear racks includes a plurality of second install holes arranged along the length direction. Each of the second support bars is fixedly installed in one of the second install holes.

In an embodiment of the present invention, a quantity of the fourth adjusting set is two. The two fourth adjusting sets are disposed separately. The fourth pinions of the two fourth adjusting sets are rotated synchronously. The odd-sequenced second support bars are fixed on the two fourth gear racks of the two fourth adjusting sets which move in the same direction. The even-sequenced second support bars are fixed on the other two fourth gear racks of the two fourth adjusting sets which move in the same direction.

In an embodiment of the present invention, the device interface further include a bearing platform. The third adjusting set further includes a third motor, and the fourth adjusting set further includes a fourth motor. The bearing platform is disposed in the spacing. The third pinion and the fourth pinion are disposed on one side of the bearing platform facing the performance board. The third motor and the fourth motor are disposed on one side of the bearing platform facing the test head. A drive shaft of the third motor passes through the bearing platform and is connected to the third pinion to control the third pinion's actuation. A drive shaft of the fourth motor passes through the bearing platform and is connected to the fourth pinion to control the fourth pinion's actuation.

According to an embodiment of the present invention, a method of adjusting the device interface is provided. The method includes adjusting the two first frames to move toward or away from each other along the Y-axis direction for bearing the performance board through the two first frames, adjusting the two second frames to move toward or away from each other along the Y-axis direction for corresponding to the probe modules of the test head, adjusting the odd-sequenced first support bars and the even-sequenced first support bars to move along the X-axis direction to enable the support pillars to slide along the second grooves, and adjusting the odd-sequenced second support bars and the even-sequenced second support bars to move along the Y-axis direction to enable the support pillars to slide along the first grooves. Viewing along one of the second support bars, the support pillars include the first support pillar to the 2m-th support pillar arranged sequentially along the X-axis direction, where m is a positive integer. A distance between the (2n-1)-th support pillar and the 2n-th support pillar corresponds to a length of each chip test socket in the X-axis direction, where n is a positive integer and n is less than or equal to m. Viewing along one of the first support bars, the support pillars include the first support pillar to the 2p-th support pillar arranged sequentially along the Y-axis direction, where p is a positive integer. A distance between the (2q-1)-th support pillar and the 2q-th support pillar corresponds to a width of each chip test socket in the Y-axis direction, where q is a positive integer and q is less than or equal to p.

The invention utilizes the first adjusting set and the second adjusting set to control the movement of the first frame and the second frame, either toward or away from each other, thereby enhancing the flexibility in the use of the test head and the performance board, and enabling compatibility for size conversion between the test head and the performance board. Furthermore, by using the third and fourth adjusting sets to adjust the displacement of the first and second support bars of the supporting structure, the distance between the support pillars located at the overlapping positions of the two support bars can be appropriately modified, effectively allowing the performance board to support chip test sockets of various sizes.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic diagram of a device interface according to an embodiment of the present invention.

FIG. 2 is a schematic exploded view of a device interface according to an embodiment of the present invention.

FIG. 3 is a schematic diagram showing a partially assembled device interface according to embodiment of the present invention.

FIG. 4 is a schematic diagram of the device interface in FIG. 3 from another perspective.

FIG. 5 is a schematic top view of a device interface and a performance board according to an embodiment of the present invention.

FIG. 6 is a schematic diagram of a chip test socket and a bearing structure according to an embodiment of the present invention.

FIG. 7 is a schematic exploded view of a third adjusting set, a fourth adjusting set, and a bearing structure according to an embodiment of the present invention.

FIG. 8 is a schematic exploded view of a device interface according to another embodiment of the present invention.

FIG. 9 is a schematic diagram showing a partially assembled device interface according to another embodiment of the present invention.

FIG. 10 is a schematic exploded view of a support base and a bearing structure according to an embodiment of the present invention.

FIG. 11 is a partial cross-sectional view of a configuration of a support base, a bearing structure, a performance board, and a chip test socket according to an embodiment of the present invention.

FIG. 12 is a flow chart of a method of adjusting a device interface according to an embodiment of the present invention.

### DETAILED DESCRIPTION OF PREFERRED EMBODIMENTS

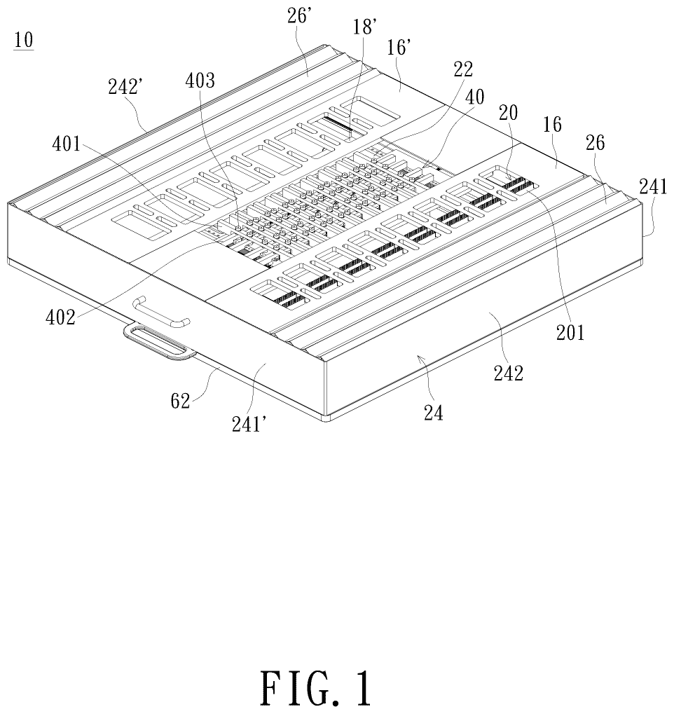

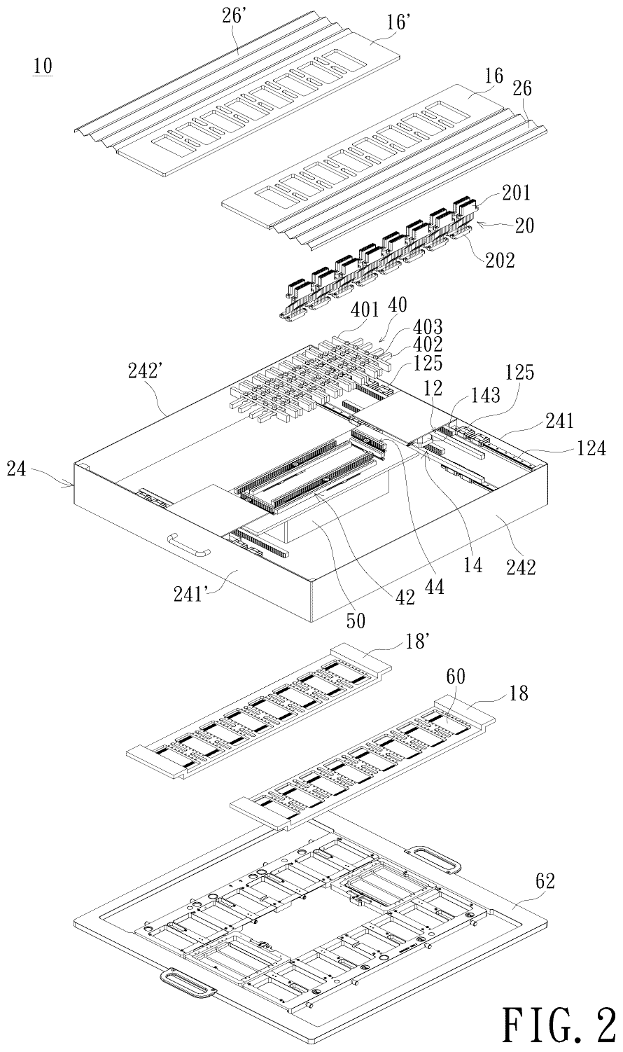

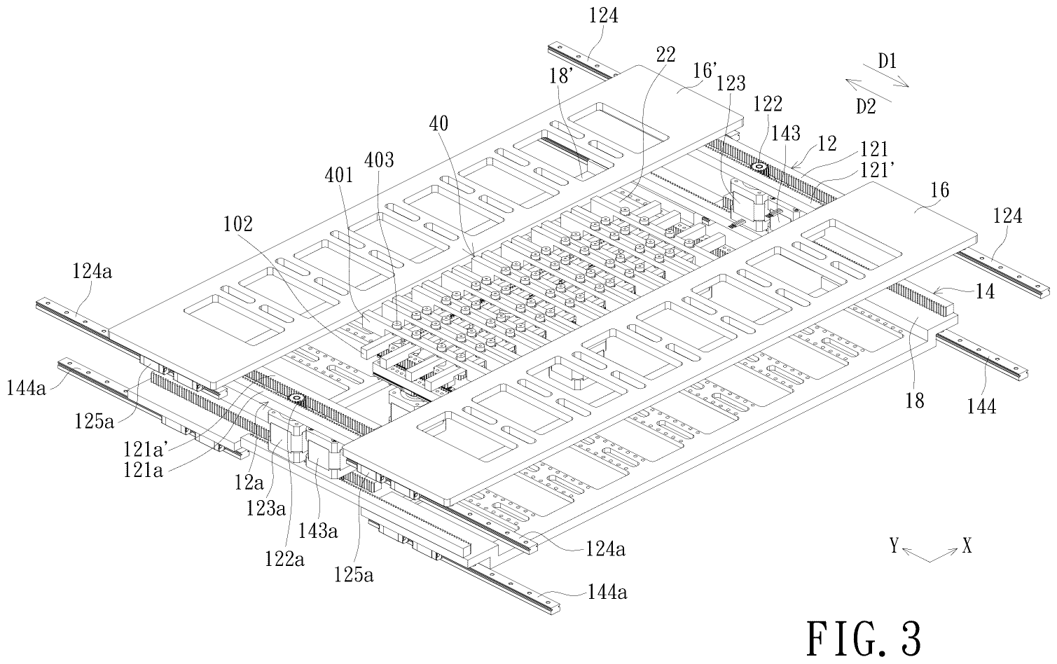

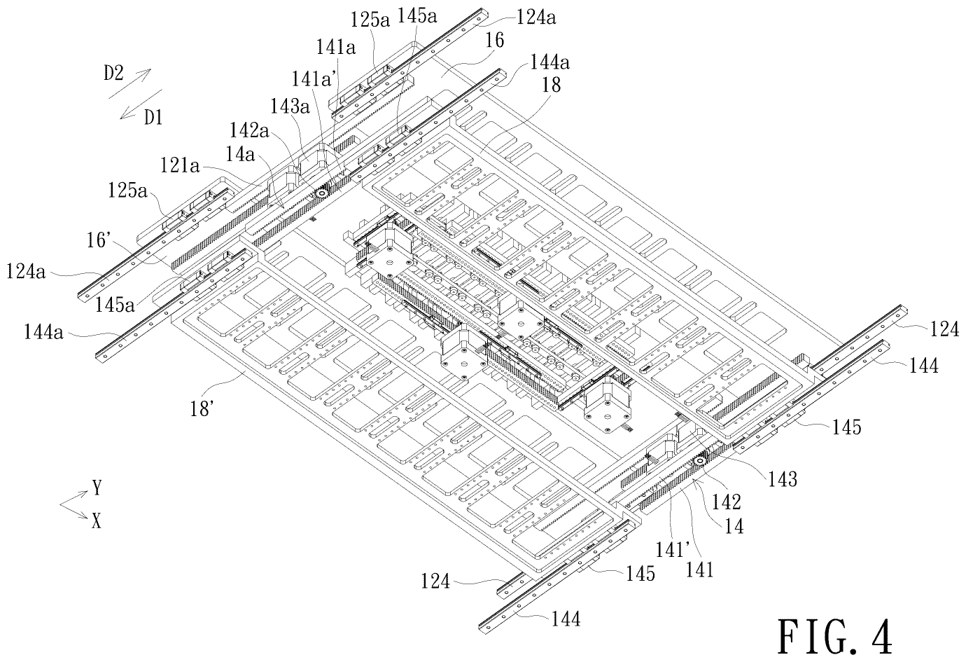

According to an embodiment of the present invention, a device interface disposed between a test head and a device under test is provided. The test head includes a plurality of probe modules. The device under test includes a performance board and a plurality of chip test sockets. The chip test sockets are disposed on the performance board and adapted for placing a chip under test. FIG. 1 is a schematic diagram of a device interface according to an embodiment of the present invention. FIG. 2 is a schematic exploded view of a device interface according to an embodiment of the present invention. As shown in FIG. 1 and FIG. 2, the device interface 10 includes a first adjusting ser 12 (illustrated in FIG. 2), a second adjusting set (illustrated in FIG. 2), two first frames 16 and 16′, two second frames 18 and 18′ (illustrated in FIG. 2), and a plurality of electrical connection parts 20. FIG. 3 is a schematic diagram showing a partially assembled device interface according to embodiment of the present invention. FIG. 4 is a schematic diagram of the device interface in FIG. 3 from another perspective. As shown in FIG. 2, FIG. 3, and FIG. 4, the two first frames 16 and 16′ are disposed in parallel on the first adjusting set 12. Through an actuation of the first adjusting set 12, the two first frames 16 and 16′ are adapted to move toward or away from each other along a Y-axis direction. There is a spacing 22 located between the two first frames 16 and 16′. The two second frames 18 and 18′ are disposed in parallel on the second adjusting set 14. Through an actuation of the second adjusting set 14, the two second frames 18 and 18′ are adapted to move toward or away from each other along the Y-axis direction. As shown in FIG. 1 and FIG. 2, each of the electrical connection parts includes a probe terminal 201 mounted on the first frames 16 or 16′ and the other probe terminal 202 mounted on the second frames 18 or 18′. In FIG. 1 and FIG. 2, only the electrical connection parts 20 mounted on the first frame 16 and the second frame 18 are illustrated for example.

In an embodiment as shown in FIG. 3, the first adjusting set 12 includes two first gear racks 121 and 121′ and a first pinion 122. The two first gear racks 121 and 121′ are parallel to each other in their length direction and extend along the Y-axis direction. The first pinion 122 is engaged between the two first gear rack 121 and 121′. In other words, the two first gear racks 121 and 121′ are engaged on two opposite sides of a radial direction of the first pinion 122. The two first gear racks 121 and 121′ are adapted to move correspondingly in the two opposite sides of the radial direction of the first pinion 122. The first frame 16 is mounted on the first gear rack 121 and the other first frame 16′ is mounted on the other first gear rack 121′. In an embodiment, the first adjusting set 12 further includes a first motor 123. A drive shaft of the first motor 123 is connected to the first pinion 122 for controlling an actuation of the first pinion 122.

In an embodiment, a quantity of the first adjusting sets 12 is two, such as the two first adjusting sets 12 and 12a shown in FIG. 2. The two first adjusting sets 12 and 12a are disposed separately. The two first frames 16 and 16′ are disposed in parallel on the first adjusting sets 12 and 12a, respectively. More particularly, the first frame 16 is disposed on the first gear racks 121 and 121a of the first adjusting sets 12 and 12a, and the first frame 16′ is disposed on the first gear racks 121′ and 121a′ of the first adjusting sets 12 and 12a. The first pinion 122 of the first adjusting set 12 and the first pinion 122a of the first adjusting set 12a rotate synchronously. The first pinions 122 and 122a could rotate synchronously in a same direction or in opposite directions according to an arrangement of the first frames 16 and 16′ and the first gear racks 121, 121a, 121′, and 121a′. As shown in FIG. 3, the two first pinions 122 and 122a rotate synchronously in opposite directions. In other words, when the first pinion 122 rotates in a first rotation direction and the first pinion 122a rotates in a second rotation direction, the first gear racks 121 and 121a move toward the same direction (such as the first direction D1) in the same speed, and the first gear racks 121′ and 121a′ move toward the same direction (such as the second direction D2) in the same speed. Since the first direction D1 and the second direction D2 are opposite each other, the first frames 16 and 16′ move away from each other. When the first pinion 122 rotates in the second rotation direction and the first pinion 122a rotates in the first rotation direction, the two first frames 16 and 16′ move toward each other.

Accordingly, as shown in FIG. 4, the second adjusting set 14 includes two second gear racks 141 and 141′ and a second pinion 142. The two second gear racks 141 and 141′ are parallel to each other in their length direction and extend along the Y-axis direction. The second pinion 142 is engaged between the two second gear rack 141 and 141′. In other words, the two second gear racks 141 and 141′ are engaged on two opposite sides of a radial direction of the second pinion 142. The second frame 18 is mounted on the second gear rack 121 and the other second frame 16′ is mounted on the other second gear rack 121′. In an embodiment, the second adjusting set 14 further includes a second motor 143. A drive shaft of the second motor 143 is connected to the second pinion 142 for controlling an actuation of the second pinion 142.

In an embodiment, as shown in FIG. 4, a quantity of the second adjusting sets 14 is two, such as the two second adjusting sets 14 and 14a shown in FIG. 2. The two second adjusting sets 14 and 14a are disposed separately. The two second frames 18 and 18′ are disposed in parallel on the second adjusting sets 14 and 14a, respectively. More particularly, the second frame 18 is disposed on the second gear racks 141 and 141a of the second adjusting sets 14 and 14a, and the second frame 18′ is disposed on the second gear racks 141′ and 141a′ of the second adjusting sets 14 and 14a. The second pinion 142 of the second adjusting set 14 and the second pinion 142a of the second adjusting set 12a rotate synchronously. The second pinions 142 and 142a could rotate synchronously in a same direction or in opposite directions according to an arrangement of the second frames 18 and 18′ and the second gear racks 141, 141a, 141′, and 14a′. As shown in FIG. 4, the two second pinions 142 and 142a rotate synchronously in opposite directions. In other words, when the second pinion 142 rotates in the first rotation direction and the second pinion 142a rotates in the second rotation direction, the second gear racks 141 and 141a move toward the same direction (such as the first direction D1) in the same speed, and the fir second gear racks 141′ and 141a′ move toward the same direction (such as the first direction D2) in the same speed. Since the directions D1 and D2 are opposite each other, the second frames 18 and 18′ move away from each other. When the second pinion 142 rotates in the second rotation direction and the second pinion 142a rotates in the first rotation direction, the two second frames 18 and 18′ move toward each other.

As shown in FIG. 1 and FIG. 2. The device interface 10 further includes a base 24. The base 24 includes two opposite first sidewalls 241 and 241′ and two opposite second sidewalls 242 and 242′. The first motor 123 (illustrated in FIG. 3) and the second motor 143 (illustrated in FIG. 3) are disposed on the first sidewall 241. As shown in FIG. 3, when the device interface 10 includes the two first adjusting sets 12 and 12a and the two second adjusting sets 14 and 14a, the two first motors 123 and 123a are disposed on the two first sidewalls 241 and 241′, and the two second motors 143 and 143a are disposed on the two first sidewalls 241 and 241′. In an embodiment, each of the first motors 123/123a and each of the second motors 143/143a are disposed in parallel on the first sidewalls 241/241′. The drive shafts of the first motors 123/123a are placed upward (the direction toward the first frames 16, 16′) to be connected to the first pinions 122/122a, respectively. The drive shafts of the second motors 143/143a are placed downward (the direction toward the second frames 18, 18′) to be connected to the second pinions 142/142a, respectively. In an embodiment not illustrated, the first motors 123/123a and the second motors 143/143a are not included. The first frames 16, 16′ and the second frames 18, 18′ are moved through a manual adjustment.

In an embodiment, as shown in FIG. 2, FIG. 3, and FIG. 4, the first adjusting sets 12/12a further include two first rails 124/124a and a plurality of first sliding docks 125/125a. The first rails 124/124a are disposed in parallel in an outer side of the first gear racks 121/121a. In an embodiment, the first rails 124/124a are supported by the first sidewalls 241/241′ of the base 24. The first sliding docks 125 and 125a are disposed on two opposite ends of the first frames 16/16′ and slidably mounted on the first rails 124/124a, respectively. When the first frame 16 is actuated along with the first gear racks 121 and 121a and the first frame 16′ is actuated along with the first gear racks 121′ and 121a′, the first sliding docks 125 and 125a are slid on the first rails 124 and 124a, respectively.

As shown in FIG. 3 and FIG. 4, the second adjusting sets 14/14a further includes two second rails 144/144a and a plurality of second sliding docks 145/145a. The second rails 144/144a is disposed parallel to the second gear rack 141/141a. In an embodiment, the second rails 144/144a are supported by a mounting frame 62 (illustrated in FIG. 1 and FIG. 2 and described in detail as below) under the base 24. The second sliding docks 145 and the second sliding docks 145a are disposed on two opposite ends of the second frames 18/18′ and slidably mounted on the second rails 144/144a. When the second frame 18 is actuated along with the second gear racks 141 and 141a and the second frame 18′ is actuated along with the second gear racks 141′ and 141a′, the second sliding docks 145 and 145a are slid on the second rails 144 and 144a, respectively.

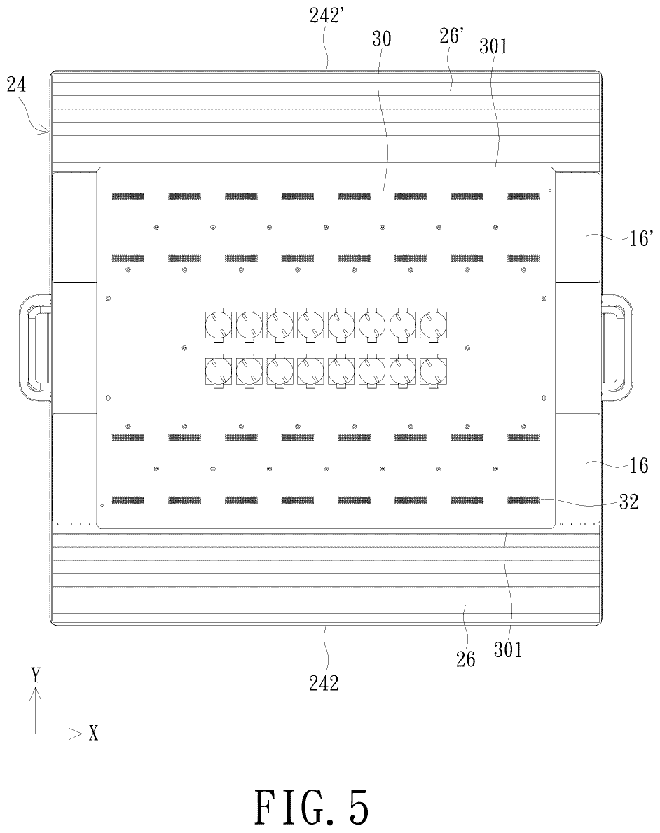

FIG. 5 is a schematic top view of a configuration of the device interface 10 and the performance board 30 according to an embodiment of the present invention. As shown in FIG. 1 and FIG. 5, the two first frames 16 and 16′ are adapted to bear the performance board 30. The two second frames 18 and 18′ (shown in FIG. 2 to FIG. 4) are adapted to correspond to the probe modules of the test head (not shown here). When applying to a large-sized performance board 30, the two first frames 16 and 16′ can move away from each other and toward the edges of the large-sized performance board for properly bearing the large-sized performance board 30 together. At the same time, the probe terminals 201 of the electrical connection parts 20 mounted on the first frames 16 and 16′ can be electrically connected to the test resource area 32 of the performance board 30. When applying to a small-sized performance board 30, the two first frames 16 and 16′ can move toward each other and become closer for properly bearing the small-sized performance board 30 together. Also, the probe terminals 201 of the electrical connection parts 20 mounted on the first frames 16 and 16′ can be electrically connected to the test resource area 32 of the performance board 30.

Different types of the test heads have probe modules with varying configurations. When the probe module occupies a smaller area, by moving the two second frames 18 and 18′ (shown in FIG. 2 to FIG. 4) toward each other, the probe terminals 202 (shown in FIG. 2) of the electrical connection parts 20 mounted on the second frame 18 and 18′ are driven to be electrically connected to the probe module. When the probe module occupies a larger area, by moving the two second frames 18 and 18′ away from each other, the probe terminals 202 (shown in FIG. 2) of the electrical connection parts 20 mounted on the second frame 18 and 18′ are driven to be electrically connected to the probe module.

The first pinions 122/122a and the second pinions 142/142a can rotate in the same or opposite directions. In other words, when the two first frames 16 and 16′ move toward each other, the two second frames 18 and 18′ can move toward or away from each other. When the two first frames 16 and 16′ move away from each other, the two second frames 18 and 18′ can move toward or away from each other. For example, when the probe module of the test head occupies a smaller area, the two second frames 18 and 18′ move toward each other. At the same time, by moving the two first frames 16 and 16′ away from each other, a larger-sized performance board 30 can be adapted to expand the space; or by moving the two first frames 16 and 16′ toward each other, a smaller-sized performance board 30 can still be adapted. Thus, a flexibility in the use of the test head and performance board 30 can be improved. In addition, when the probe module of the test head occupies a larger area, the two second frames 18 and 18′ move away from each other and the performance board 30 with a proper size can be adapted based on the requirement. By moving the two first frames 16 and 16′ toward or away from each other, the performance board 30 with varying sizes can be fitted, thereby improving the compatibility for size conversion between the test head and the performance board 30.

As shown in FIG. 1, FIG. 2 and FIG. 5, the device interface 10 further includes two retractable dust protection caps 26 and 26′ which are connected between the first frames 16/16′ and the second sidewalls 242/242′. When the two first frames 16 and 16′ move toward each other along the Y-axis direction, the retractable dust protection caps 26 and 26′ are elongated. When the two first frames 16 and 16′ move away from each other along the Y-axis direction, the retractable dust protection caps 26 and 26′ are compressed. Through the elongation and compression, the retractable dust protection caps 26 and 26′ can effectively cover an area adjacent to the second sidewalls 242 and 242′ on the base 24 (the area not covered by the performance board 30) to prevent environmental dust from falling into the base 24, thereby achieving an effective dustproof effect.

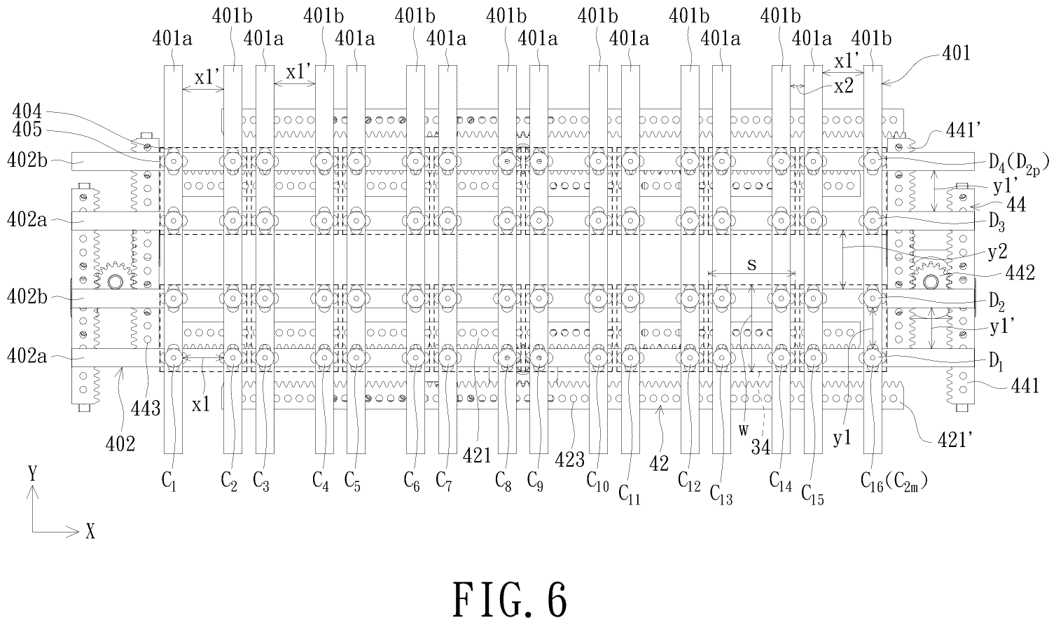

As shown in FIG. 5, when the performance board 30 is supported by the first frames 16 and 16′, the plurality of the chip test sockets 34 disposed in a central region of the performance board 30 correspond to the spacing 22 between the first frames 16 and 16′ (shown in FIG. 1). To better support the chip test socks 34, as shown in FIG. 1, FIG. 2, and FIG. 3, the device interface 10 further includes a bearing structure 40, a third adjusting set 42, and a fourth adjusting set 44 which are disposed corresponding to the spacing 22. In an embodiment, the bearing structure 40 includes a plurality of first support bars 401, a plurality of second support bars 402, and a plurality of support pillars 403. The first support bars 401 and the second support bars 402 are disposed in a crossing arrangement. The support pillars 403 are disposed at locations where the first support bars 401 and the second support bars 402 cross each other. FIG. 6 is a schematic diagram of a chip test socket and a bearing structure according to an embodiment of the present invention. Here, the performance board 30 is omitted for clarity. As shown in FIG. 6, each of the chip test sockets 34 (shown as a dashed lines frame) is supported together by the four adjacent support pillars 403 located at four corners. Preferably, the four support pillars 403 support the four corners of the chip test socket 34 through the performance board 30 interposed therebetween (shown in FIG. 5), thereby achieving a better support effect. Optionally, in an embodiment, the support pillars 403 can be disposed on other positions besides the four corners of the chip test socket 34. A combination of any positions under the chip test socket 34 can be used according to the requirement.

As shown in FIG. 6, viewing along one of the second support bars 402, the support pillars 403 are disposed at the locations where the first support bars 401 and the second support bars 402 cross each other, and include the first support pillar C1, the second support pillar C2, the third support pillar C3, . . . to the 2m-th support pillar C2m arranged sequentially along the X-axis direction, where m is a positive integer. A distance x1 between the (2n-1)-th support pillar and the 2n-th support pillar is corresponding to a length s of each of the chip test sockets 34 in the X-axis direction, where n is a positive integer and n is less than or equal to m. For example, as shown in FIG. 6, viewing along one of the second support bars 402, the first support pillar C1, the second support pillar C2, the third support pillar C3, . . . the fifteenth support pillar C15, and the sixteenth support pillar C16 (that is m=8) are arranged sequentially. The distance x1 between the first support pillar C1 and the second support pillar C2 (where n=1), the distance x1 between the third support pillar C3 and the fourth support pillar C4 (where n=2), . . . the distance x1 between the fifteenth support pillar C15 and the sixteenth support pillar C16 (where n=8) are respectively corresponding to the length s of each of the chip test sockets 34 in the X-axis direction. In the embodiment shown in FIG. 6, each of the lengths s of the chip test sockets 34 is the same, and each of the distances x1 is the same. However, the invention is not limited thereto.

Correspondingly, viewing along one of the first support bars 401, the support pillars 403 are disposed at the locations where the first support bars 401 and the second support bars 402 cross each other, and include the first support pillar D1, the second support pillar D2, the third support pillar D3, . . . to the 2p-th support pillar D2p arranged sequentially along the Y-axis direction, where p is a positive integer. A distance y1 between the (2q-1)-th support pillar and the 2q-th support pillar is corresponding to a width w of each of the chip test sockets 34 in the Y-axis direction, where q is a positive integer and q is less than or equal to p. For example, viewing along one of the first support bars 401, the first support pillar D1, the second support pillar D2, the third support pillar D3, and the fourth support pillar D4 (where p=2) are arranged sequentially. The distance y1 between the first support pillar D1 and the second support pillar D2, and the distance y2 between the third support pillar D3 and the fourth support pillar D4 are respectively corresponding to the width w of each chip test socket 34 in the Y-axis direction. In the embodiment shown in FIG. 6, each of the widths w of the chip test sockets 34 is the same, and each of the distances y1 is the same. However, the invention is not limited thereto.

Accordingly, the distance x1 between two laterally adjacent support pillars 403 may correspond to the lateral length s of a single chip test socket 34, and the distance y1 between two longitudinally adjacent support pillars 403 may correspond to the longitudinal width w of the chip test socket 34. As a result, the four adjacent support pillars 403, distributed at the four corners, may respectively abut, with the performance board 30 interposed therebetween (as illustrated in FIG. 5), against the four corners of the chip test socket 34, thereby collectively supporting the chip test socket 34.

Furthermore, in response to chip test sockets 34 of varying sizes, the first support bar 401 and the second support bar 402 are adjusted through the third adjusting set 42 and the fourth adjusting set 44, thereby allowing for the appropriate adjustment of the distance x1/y1 between the support pillars 403. This enables an effective support for chip test sockets 34 of different sizes. The detailed operation of the adjustment is described in the following.

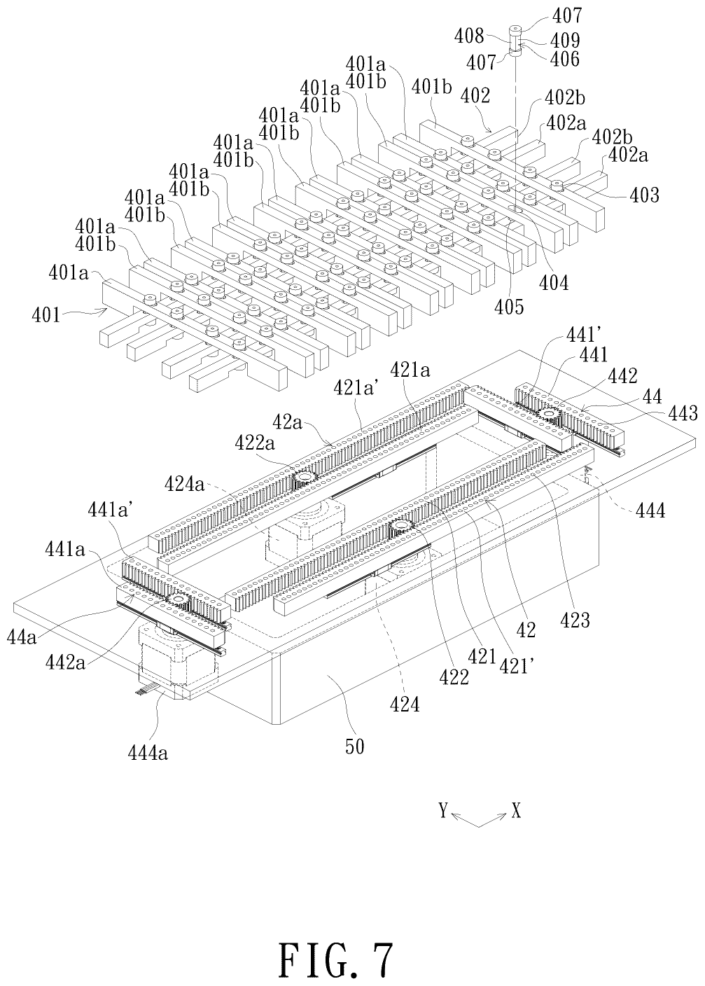

FIG. 7 is a schematic exploded view of a third adjusting set, a fourth adjusting set, and a bearing structure according to an embodiment of the present invention. As shown in FIG. 6 and FIG. 7, a plurality of first support bars 401 are arranged along the X-axis direction on a third adjusting set 42. The first support bars 401 include the odd-sequenced first support bars 401a and the even-sequenced first support bars 401b. With an actuation of the third adjusting set 42, the odd-sequenced first support bars 401a and the even-sequenced first support bars 401b move toward opposite directions along the X-axis. More specifically, in an embodiment, the third adjusting set 42 includes two third gear racks 421 and 421′ and a third pinion 422. The third gear racks 421 and 421′ are parallel to each other in their length direction and extend along the X-axis direction. The third pinion 422 is engaged between the two third gear racks 421 and 421′. The two third gear racks 421 and 421′ are adapted to move in opposite sides of the radial direction of the third pinion 422. The odd-sequenced first support bars 401a are fixed on the third gear rack 421 and the even-sequenced first support bars 401b are fixed on the third gear rack 421′. By actuating the third pinion 422, the odd-sequenced first support bars 401a and the adjacent even-sequenced first support bars 401b can move toward or away from each other.

For example, the first support bars 401 are arranged along the X-axis direction from left to right in the following order: the first, the second, the third, . . . the fifteenth, and the sixteenth of the first support bars 401. The odd-sequenced first support bars 401a (including the first, the third, . . . and the fifteenth of the first support bars) are fixed on the third gear rack 421. The even-sequenced first support bars 401b (including the second, the fourth, . . . and the sixteenth of the first support bars) are fixed on the third gear rack 421′. When the third pinion 422 rotates in a rotation direction, such as counterclockwise, the odd-sequenced first support bars 401a move synchronously toward the same direction, such as the right, and the even-sequenced first support bars 401b move synchronously toward the same direction, such as the left. Under this conditions, the distance x1′ between the first and the second of the first support bars 401, the distance x1′ between the third and the fourth of the first support bars 401, . . . and the distance x1′ between the fifteenth and the sixteenth of the first support bars 401 are decreased. In the contrary, when the third pinion 422 rotates in another rotation direction, such as clockwise, the odd-sequenced first support bars 401a move synchronously toward the same direction, such as the left, and the even-sequenced first support bars 401b move synchronously toward the same direction, such as the right. Under this condition, the distance x1′ between the first and the second of the first support bars 401, the distance x1′ between the third and the fourth of the first support bars 401, . . . and the distance x1′ between the fifteenth and the sixteenth of the first support bars 401 are increased.

As a continuation of the foregoing description, the first support bars 401 and the second support bars 402 are arranged to cross each other. The plurality of second support bars 402 are disposed along the Y-axis on the fourth adjusting set 44. The second support bars 402 include the odd-sequenced second support bars 402a and the even-sequenced second support bars 402b. Through an actuation of the fourth adjusting set 44, the odd-sequenced second support bars 402a and the even-sequenced second support bars 402b move toward opposite directions along the Y-axis. More specifically, in an embodiment, the fourth adjusting set 44 includes two fourth gear racks 441 and 441′ and a fourth pinion 442. The fourth gear racks 441 and 441′ are parallel to each other in their length direction and extend along the Y-axis direction. The fourth pinion 442 is engaged between the two fourth gear racks 441 and 441′. The two fourth gear racks 441 and 441′ are adapted to move in two opposite sides of the radial direction of the fourth pinion 442. The odd-sequenced second support bars 402a are fixed on the fourth gear rack 441 and the even-sequenced second support bars 402b are fixed on the fourth gear rack 441′. By actuating the fourth pinion 442, the odd-sequenced second support bars 402a and the adjacent even-sequenced second support bars 402b can move toward or away from each other.

For example, the second support bars 402 are arranged along the Y-axis direction from front to back in the following order: the first, the second, the third, and the fourth of the second support bars 402. The odd-sequenced second support bars 402a (including the first and the third of the second support bars 402) are fixed on the fourth gear rack 441. The even-sequenced second support bars 402b (including the second and the fourth of the first support bars 402) are fixed on the fourth gear rack 441′. When the fourth pinion 442 rotates in a rotation direction, the odd-sequenced second support bars 402a move synchronously in the same direction, such as toward back, and the even-sequenced second support bars 402b move synchronously in the same direction, such as toward front. Thus, a distance y1′ between the first and the second of the second support bars 402 and a distance y1′ between the third and the fourth of the second support bars 402 are increased. In the contrary, when the fourth pinion 442 rotates in another rotation direction, the odd-sequenced second support bars 402a move synchronously in the same direction, such as toward front, and the even-sequenced second support bars 402b move synchronously in the same direction, such as toward back. Thus, the distance y1′ between the first and the second of the second support bars 402 and the distance y1′ between the third and the fourth of the second support bars 402 are decreased.

As shown in FIG. 6 and FIG. 7, each of the first support bars 401 includes a plurality of first grooves 404 formed in the length direction of the first support bars 401, and each of the second support bars 402 includes a plurality of second grooves 405 formed in the length direction of the second support bars 402. Each of the first grooves 404 and each of the second grooves 405 are disposed at the locations where the first support bars 401 and the second support bars cross each other. In other words, at each intersection, the first grove 404 and the second groove 405 form a cross shape. The support pillars 403 are disposed on one of the locations where the first grooves 404 and the second grooves 405 overlap. FIG. 6 and FIG. 7 illustrate an example in which the first support bars 401 overlap crosswise above the second support bars 402. The invention is not limited thereto. The second support bars 402 can overlap crosswise above the first support bars 401.

As shown in FIG. 7, the support pillars 403 are illustrated separately to describe in detail. Each of the support pillars 403 includes a body 406 and two extension sections 407. The two extension sections 407 are disposed on two opposite end of the body 406, respectively. In an embodiment, the body 406 is a rectangular cuboid, for example, including a left side face 408, a right side face (not marked), a front side face 409, and a back side face (not marked). In an embodiment, each of extension sections 407 is a disc-like shape, for example. The outer diameter of the extension section 407 is greater than the outer diameter of the body 406. The body 406 is placed at the location where the first groove 404 and the second groove 405 overlap. The two extension sections 407 are adapted to limit the bodies 406 from moving upward or downward. When the support pillar 403 is disposed at the position where the first groove 404 and the second groove 405 overlap, the left side face 408 and the right side face of the body 406 abut against an inner edge of the first groove 404, and the front side face 409 and the back side face of the body 406 abut against an inner edge of the second groove 405. When the first support bars 401 (including the odd-sequenced first support bars 401a and the even-sequenced first support bars 401b) move toward the left/right side along the X-axis, the support pillars 403 slide along the second grooves 405. When the second support bars 402 (including the odd-sequenced second support bars 402a and the even-sequenced second support bars 402b) move forward/backward along the Y-axis, the support pillars 403 slide along the first grooves 404. In other words, a function of the first grooves 404 and the second grooves 405 is to provide the support pillars 403 a movement space on the first support bars 401 and the second support bars 402. The lengths of the first grooves 404 and the second grooves 405 can be adjusted according to the requirements. In addition, the first grooves 404 and the second grooves 405 also provide a function of position limitation. For example, after the position of the second support bar 402 is determined, the support pillar 403 does not move along the second support bar 403 during adjusting the first support bar 401.

As mentioned above, with the actuation of the third adjusting set 42 and the fourth adjusting set 44, the distance x1 between the two support pillars 403 adjacent to each other along the X-axis can be adjusted to fit the varying lengths s of the different chip test sockets 34. In the same manner, the distance y1 between the two support pillars 403 adjacent to each other along the X-axis can be adjusted to fit the varying widths w of the different chip test sockets 34. Thus, the four adjacent support pillars 403 distributed at four corners can abut against the four corners of the chip test socket 34 through the performance board 30 therebetween, thereby collectively supporting one chip test socket 34. The movable range of two support pillars 403 adjacent to each other along the X-axis is limited by the length of the second groove 405, while the movable range of two support pillars 403 adjacent to each other along the Y-axis is limited by the length of the first groove 404. In other words, the support pillars 403 are freely slidable within the supported range defined by the first grooves 404 and the second grooves 405. In addition, the sizes of the first grooves 404 and the second grooves 405 can be adjusted according to the requirements.

In an embodiment, as shown in FIG. 6 and FIG. 7, the third gear racks 421 and 421′ include a plurality of first install holes 423 along their length direction. Each of the first support bars 401 is fixedly installed in one of the first install holes 423. The fourth gear racks 441 and 441′ include a plurality of second install holes 443 along their length direction. Each of the second support bars 402 is fixedly installed in one of the second install holes 443. In an embodiment, the first install holes 423 and the second install holes 443 are screw holes, for example. The first support bars 401 and the second support bars 402 are secured to the screw holes by means of, for example, screws (not illustrated). Thus, the first support bars 401 and the second support bars 402 are secured on the third gear racks 421/421′ and the fourth gear racks 441/441′.

Through a dense arrangement of the first install holes 423, the positions of the odd-sequenced first support bars 401a and the even-sequenced first support bars 401b in the third gear racks 421/421′ are pre-adjusted according to the distance between the two adjacent chip test sockets 34 along the X-axis, such that a distance x2 between each even-sequenced first support bar 401b and its adjacent higher-ordered odd-sequenced first support bar 401a corresponds to the distance between the two adjacent chip test sockets 34 along the X-axis. Correspondingly, through a dense arrangement of the second install holes 443, the positions of the odd-sequenced second support bars 402a and the even-sequenced second support bars 402b in the fourth gear racks 441/441′ are pre-adjusted according to the distance between the two adjacent chip test sockets 34 along the Y-axis, such that a distance y2 between each even-sequenced second support bar 402b and its adjacent higher-ordered odd-sequenced second support bar 402a corresponds to the distance between the two adjacent chip test sockets 34 along the Y-axis.

In other words, the first install holes 423 and the second install holes 443 provide adjustable installation positions for the first support bars 401 and the second support bars 402, respectively. By adjusting the installation positions, the values of the distances x2 and y2 can be correspondingly adjusted. After that, the values of the distances x1′ and y1′ can be adjusted through the actuations of the third pinion 422 and the fourth pinion 442. As a result, the distribution flexibility of the support pillars 403 can be further improved, thereby supporting the four corners of the chip test sockets 34, through the interposed performance board 30, more precisely. Furthermore, the distances between the two adjacent chip test sockets 34 along the X-axis can be the same or different. The distances between the two adjacent chip test sockets 34 along the Y-axis can be the same or different.

As shown in FIG. 7, the device interface 10 further includes a bearing platform 50 disposed in the base 24 and located within the space 22 (shown in FIG. 1). In an embodiment, the device interface 10 includes two third adjusting sets 42 and two fourth adjusting sets 44. The two third adjusting sets 42 are disposed separately (such as adjacent to the front/back sides of the bearing platform 50 respectively). The two fourth adjusting sets 44 are disposed separately (such as adjacent to the right/left sides of the bearing platform 50 respectively). The third pinions 422/422a of the third adjusting sets 42/42a and the fourth pinions 442/442a of the fourth adjusting sets 44/44a are disposed on one side of the bearing platform 50 facing the performance board 30 (shown in FIG. 5). In addition, the third adjusting sets 42/42a further include third motors 424/424a. The fourth adjusting sets 44/44a further include fourth motors 444/444a. The third motors 424/424a and the fourth motors 444/444a are disposed on the other side of the bearing platform 50 which is adjacent to the test head (not illustrated). The drive shafts of third motors 424/424a pass through the bearing platform 50 and are connected to the third pinions 422/422a for controlling the actuation of the third pinions 422/422a. The drive shafts of fourth motors 444/444a pass through the bearing platform 50 and are connected to the fourth pinions 442/442a for controlling the actuation of the fourth pinions 442/442a.

Continuing from the foregoing description, the third pinions 422 and 422a of the two third adjusting sets 42 and 42a rotate synchronously. The odd-sequenced first support bars 401a are fixed on the two third gear racks 421 and 421a of the third adjusting sets 42 and 42a which move toward the same direction. The even-sequenced first support bars 401b are fixed on the other two third gear racks 421′ and 421a′ of the third adjusting sets 42 and 42a which move toward the same direction. The fourth pinions 44 and 442a of the two fourth adjusting sets 44 and 44a rotate synchronously. The odd-sequenced second support bars 402a are fixed on the two fourth gear racks 441 and 441a of the fourth adjusting sets 44 and 44a which move toward the same direction. The even-sequenced second support bars 402b are fixed on the other two fourth gear racks 441′ and 441a′ of the fourth adjusting sets 44 and 44a which move toward the same direction.

The third pinions 422 and 422a are designed to rotate synchronously in either the same or the opposite rotation directions according to the arrangement of the odd-sequenced first support bars 401a and the even-sequenced first support bars 401b on the third gear racks 421, 421a, 421′, and 421a′. Correspondingly, the fourth pinions 442 and 442a are designed to rotate synchronously in either the same or the opposite rotation directions according to the arrangement of the odd-sequenced second support bars 402a and the even-sequenced second support bars 402b on the fourth gear racks 441, 441a, 441′, and 441a′. As shown in FIG. 6 and FIG. 7, the two third pinions 422 and 422a rotate synchronously in the opposite rotation directions. The two fourth pinions 442 and 442a rotate synchronously in the opposite rotation directions. However, the invention is not limited thereto.

In an embodiment, as shown in FIG. 1 and FIG. 2, the device interface 10 further includes a device interface board 60 and a mounting frame 62. The mounting frame 62 is adapted to be assembled on the test head. The device interface board 60 is disposed between the second frames 18/18′ and the mounting frame 62 through the support of the mounting frame 62, such that the probe terminals 202 of the electrical connection parts 20 on the second frames 18/18′ are electrically connected to the test head through the device interface board 60. The invention is not limited thereto. In an embodiment not illustrated, the device interface board and the mounting frame are not included, and the probe terminals of the electrical connection parts on the second frames are electrically connected to test head directly.

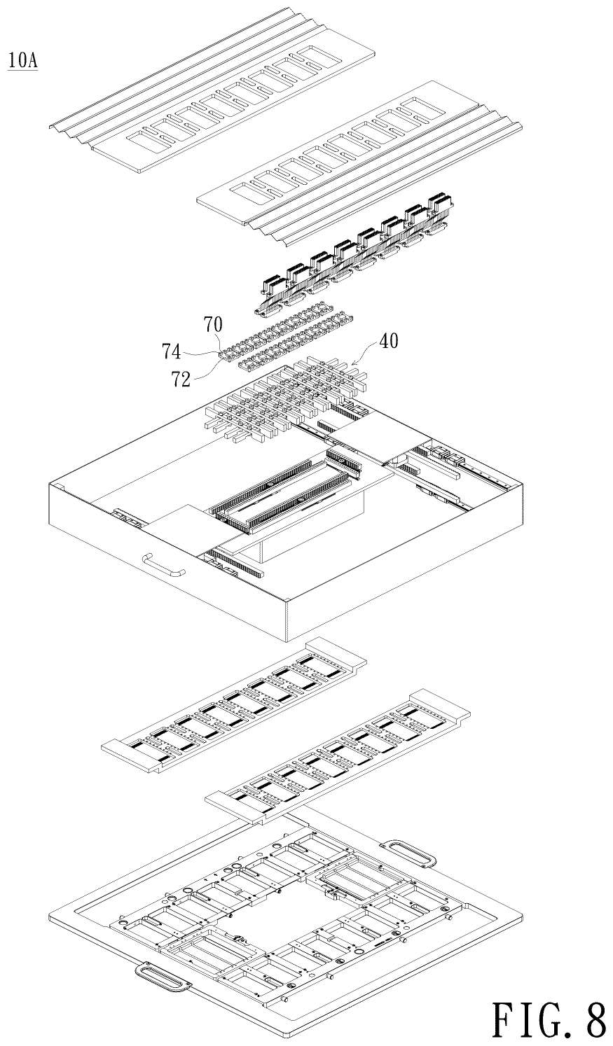

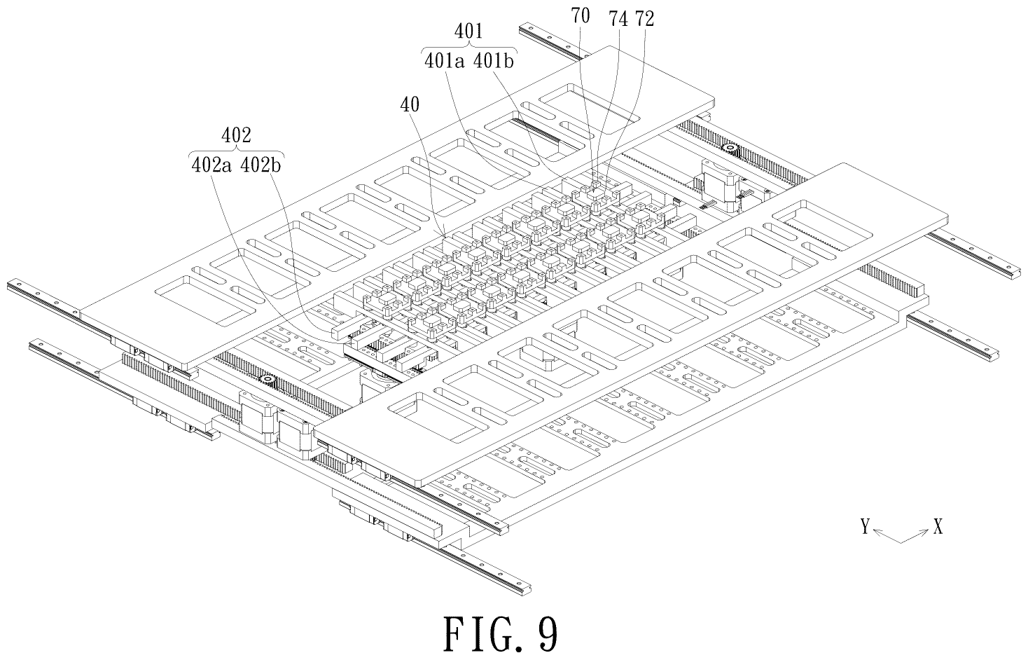

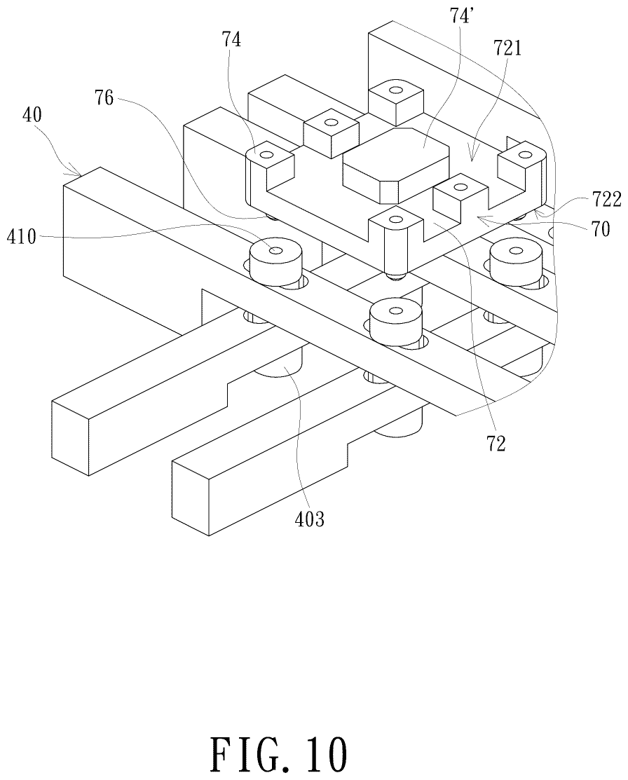

FIG. 8 is a schematic exploded view of a device interface according to another embodiment of the present invention. FIG. 9 is a schematic diagram showing a partially assembled device interface according to another embodiment of the present invention. As shown in FIG. 8 and FIG. 9, the device interface 10A further includes a plurality of support bases 70. The support bases 70 are disposed on the bearing structure 40. Other structures and configurations have been disclosed in FIG. 2 and FIG. 3, and are not reiterated here. FIG. 10 is a schematic exploded view of a support base and a bearing structure according to an embodiment of the present invention. As shown in FIG. 8 to FIG. 10, each of the support bases 70 includes a mani body 72 and a plurality of protruding platform sections 74 and 74′. As shown in FIG. 10, the main body 72 includes a first surface 721 and a second surface 722 opposite each other. The protruding platform sections 74 and 74′ are formed on the first surface 721. In an embodiment, the protruding platform sections 74 are, for example, distributed in a peripheral region of the first surface 721 and the protruding platform sections 74′ are, for example, distributed in a central region the first surface 721.

Continuing from the foregoing description, the support base 70 is collectively supported at its four corners by the two (2q-1)-th support pillars 403 and the two 2q-th support pillars 403 which are located on the two adjacent first support bars 401, or the support base 70 is collectively supported by the two (2n-1)-th support pillars 403 and the two 2n-th support pillars 403 which are located on the two adjacent second support bars 402. For example, as shown in FIG. 6 and FIG. 8, one of the support bases 70 is collectively supported by the third support pillar D3 and the fourth support pillar D4 on one odd-sequenced first support bar 401a, and the third support pillar D3 and the fourth support pillar D4 on the adjacent higher-order even-sequenced first support bar 401b. In other words, viewing from the second support bar 402, the support bases 70 is collectively supported by the first support pillar C1 and the second support pillar C2 on the odd-sequenced first support bar 402a, and the first support pillar C1 and the second support pillar C2 on the adjacent higher-order even-sequenced second support bar 402b.

As shown in FIG. 10, the support base 70 further includes four insert sections 76 formed on the second surface 722. In an embodiment, the insert sections 76 are disposed, for example, at the four corners of the second surface 722. Correspondingly, each of the support pillars 403 on the veering structure 40 includes a slot 410. The support base 70 is assembled onto the bearing structure 40 by inserting the four insert sections 76 into the slots 410 of the support pillars 403 distributed at the four corners of the support base 70, respectively.

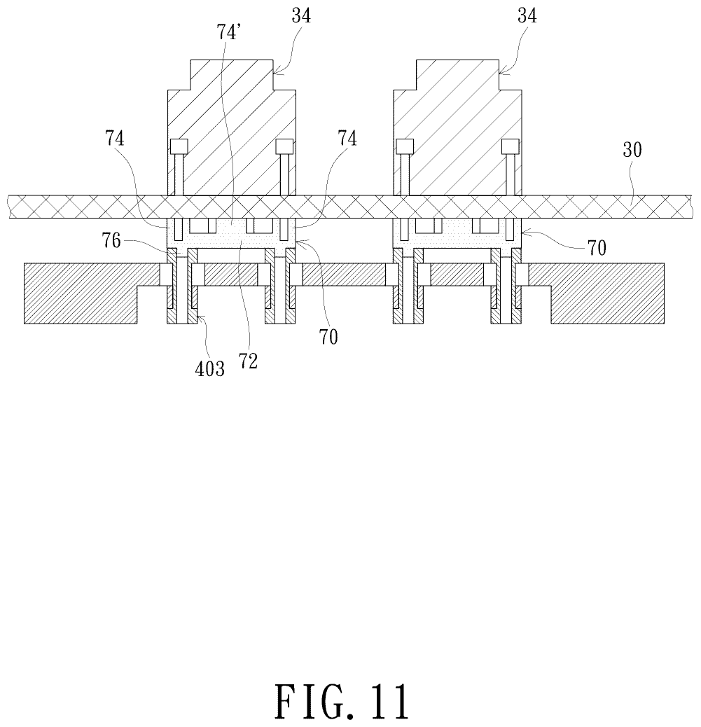

FIG. 11 is a partial cross-sectional view of a configuration of a support base, a bearing structure, a performance board, and a chip test socket according to an embodiment of the present invention. Here, two support bases 70 and two chip test sockets 34 are illustrated. As shown in FIG. 11, the insert sections 76 of the support bases 70 are inserted into the slots 410 of the support pillars 403. The protruding platform sections 74 and 74′ of the support base 70 abut against the performance board 30 and further support the chip test sockets 34 through the performance board 30 in advance. Since there are the plurality of protruding platform sections 74 and 74′ disposed on the main bodies 72 of the support base 70, the distribution of the protruding platform sections 74 and 74′ is not limited to the four corners, but can be configured according to the structure analysis. Accordingly, the plurality of protruding platform sections 74 and 74′ may be effectively distributed over both the peripheral region and the central region of the first surface 721 of the main body 72, thereby enabling stable support of the chip test socket 34 through the performance board 30. This configuration prevents the portion of the performance board 30 carrying the central region of the chip test socket 34 from becoming suspended in an unstable state, and thereby ensures the testing stability of the chip under test.

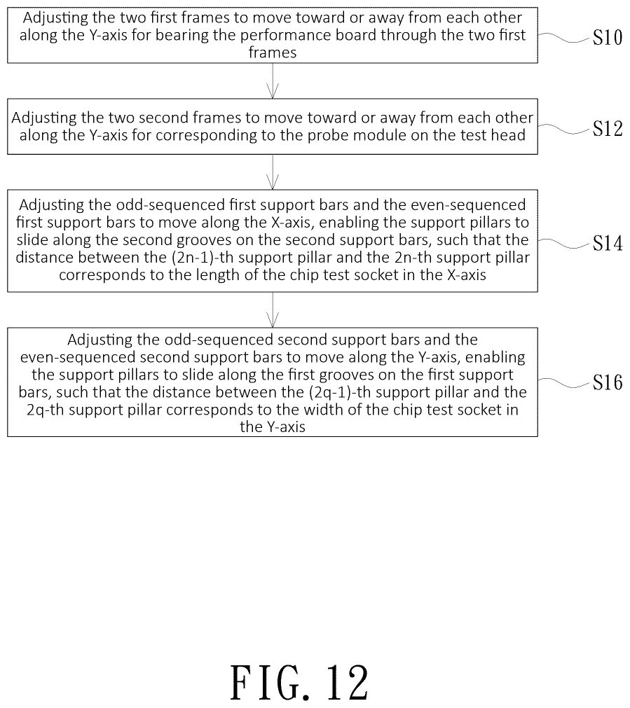

FIG. 12 is a flow chart of a method of adjusting a device interface according to an embodiment of the present invention. As shown in FIG. 12, in a method of adjusting the device interface mentioned above, the two first frames 16 and 16′ are adjusted to move toward or away from each other along the Y-axis for bearing the performance board 30 through the two first frames 16 and 16′ (S10). The two second frames 18 and 18′ are adjusted to move toward or away from each other along the Y-axis for corresponding to the probe module on the test head (S12). There is no limitation on the order of S10 and S12. Next, the odd-sequenced first support bars 401a and the even-sequenced first support bars 402b are adjusted to move along the X-axis, enabling the support pillars 403 to slide along the second grooves 405 on the second support bars 402 (S14). The odd-sequenced second support bars 402a and the even-sequenced second support bars 402b are adjusted to move along the Y-axis, enabling the support pillars 403 to slide along the first grooves 404 on the first support bars 401 (S16). There is no limitation on the order of S10 and S12.

Viewing along one of the second support bars 402, the support pillars 403 disposed at the position where the first support bars 401 and the second support bar 402 are arranged sequentially along the X-axis from the first support pillar C1, the second support pillar C2, the third support pillar C3, . . . , to the 2m-th support pillar C2m where m is a positive integer. Through sliding the support pillars 403 along the second grooves 405, the distance x1 between the (2n-1)-th support pillar C2n-1 and the 2n-th support pillar C2n corresponds to the length s of the chip test socket 34 in the X-axis, where n is a positive integer and n is less than or equal to m. Also, viewing along one of the first support bars 401, the support pillars 403 disposed at the position where the first support bar 401 and the second support bars 402 are arranged sequentially along the Y-axis from the first support pillar D1, the second support pillar D2, the third support pillar D3, . . . , to the 2p-th support pillar C2p where p is a positive integer. Through sliding the support pillars 403 along the first grooves 404, the distance y1 between the (2q-1)-th support pillar C2q-land the 2q-th support pillar C2q corresponds to the width w of the chip test socket 34 in the Y-axis, where q is a positive integer and q is less than or equal to p.

As mentioned above, the device interface and the method of adjusting the device interface according to the present invention include at least one advantage as below.

(1) When the probe module of the test head occupies a relatively small area, the two first frames may be moved away from each other to allow for the selection of a larger performance board to expand the available space, or alternatively, the two first frames may be moved toward each other to accommodate the use of a smaller performance board. Accordingly, the flexibility in utilizing the test head and the performance board is enhanced.

(2) When the probe module of the test head occupies a relatively large area, a performance board of a proper size may be selected according to the requirement. The performance board can be supported by moving the two first frames toward or away from each other, thereby achieving compatibility for size conversion between the test head and the performance board.

(3) To fit chip test sockets of various sizes disposed on the performance board, the first support bars and the second support bars of the bearing structure may be shifted to properly adjust the distance between the support pillars, thereby enabling effective support of chip test sockets of different sizes through the performance board. Furthermore, through a dense arrangement of the install holes on the gear racks, adjustable installation positions for the first and second support bars are made available, thereby further enhancing the flexibility in the distribution of the support pillars.

(4) A plurality of support bases corresponding to the chip test sockets are provided on the bearing structure. The chip test sockets are supported through the performance board by a plurality of protruding platform sections distributed uniformly or broadly on each of the support bases. This configuration prevents the performance board from bending due to the larger size or heavier weight of the chip test sockets or other adverse effects on test quality, thereby achieving a better test quality.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A device interface disposed between a test head and a device under test, the test head comprising a plurality of probe modules, the device under test comprising a performance board and a plurality of chip test sockets disposed on the performance board, the device interface comprising:
at least one first adjusting set;
at least one second adjusting set;
two first frames disposed in parallel on the at least one first adjusting set, wherein the two first frames are adapted to move toward or away from each other along a Y-axis direction through an actuation of the at least one first adjusting set, a spacing is located between the two first frames, and the two first frames are adapted to bear the performance board;
two second frames disposed in parallel on the at least one second adjusting set, wherein the two second frames are adapted to move toward or away from each other along the Y-axis direction through an actuation of the at least one second adjusting set, and the two second frames are adapted to correspond to the probe modules of the test head; and
a plurality of electrical connection parts, wherein each of the electrical connection parts comprises one end installed in one of the two first frames and electrically connected to the performance board, and the other end installed in one of the two second frames and electrically connected to the probe module.

2. The device interface according to claim 1, wherein the at least one first adjusting set comprises two first gear racks and a first pinion, the two first gear racks are parallel to each other in their length direction and extend along the Y-axis direction, the first pinion is engaged between the first gear racks, the first gear racks are adapted to move correspondingly on opposite sides of a radial direction of the first pinion, one of the two first frames is disposed on one of the first gear racks, and the other first frame is disposed on the other first gear rack.

3. The device interface according to claim 2, wherein the at least one first adjusting set further comprises two first rails and a plurality of first sliding docks, the first rails are disposed parallel to the first gear racks, the first sling docks are disposed on two opposite ends of the two first frames and mounted on the first rails, and when the two first frames are actuated along the first gear racks, the first sliding docks slide on the first rails respectively.

4. The device interface according to claim 2, wherein a quantity of the at least one first adjusting set is two, the two first adjusting sets are disposed separately, the two first frames are disposed in parallel on the two first adjusting sets, and the first pinions of the two first adjusting sets are rotated synchronously.

5. The device interface according to claim 2, wherein the at least one second adjusting set comprises two second gear racks and a second pinion, the two second gear racks are parallel to each other in their length direction and extend along the Y-axis direction, the second pinion is engaged between the second gear racks, the second gear racks are adapted to move correspondingly on opposite sides of a radial direction of the second pinion, one of the two second frames is disposed on one of the two second gear racks, and the other second frame is disposed on the other second gear rack.

6. The device interface according to claim 5, wherein the at least one second adjusting set further comprises two second rails and a plurality of second sliding docks, the second rails are disposed parallel to the second gear racks, the second sliding docks are disposed on two opposite ends of the two second frames and mounted on the second rails, and when the two second frames are actuated along the second gear racks, the second sliding docks slide on the second rails respectively.

7. The device interface according to claim 5, wherein a quantity of the at least one second adjusting set is two, the two second adjusting sets are disposed separately, the two second frames are disposed in parallel on the two second adjusting sets, and the second pinions of the two second adjusting sets are rotated synchronously.

8. The device interface according to claim 5, wherein a rotation direction of the first pinion is opposite to or the same as that of the second pinion.

9. The device interface according to claim 5 further comprises a base, wherein the at least one first adjusting set further comprises a first motor, the at least one second adjusting set further comprises a second motor, the base comprises two first sidewalls opposite to each other, the first motor and the second motor are disposed on the first sidewalls, a drive shaft of the first motor is connected to the first pion for controlling the first pinion's actuation, and a drive shaft of the second motor is connected to the second pinion for controlling the second pinion's actuation.

10. The device interface according to claim 5 further comprises a base and two retractable dust protection caps, wherein the base comprises two second sidewalls opposite to each other, each of the retractable dust protection caps is connected between each of the two first frames and each of the second sidewalls, the retractable dust protection caps are elongated when the two first frames move toward each other along the Y-axis direction, and the retractable dust protection caps are compressed when the two first frames move away from each other along the Y-axis direction.

11. The device interface according to claim 1 further comprises at least one third adjusting set, at least one fourth adjusting set, and a bearing structure in the spacing, wherein the bearing structure comprises a plurality of first support bars, a plurality of second support bars, and a plurality of support pillars,
the first support bars are arranged along an X-axis direction on the at least one third adjusting set, the first support bars comprise a plurality of odd-sequenced first support bars and a plurality of even-sequenced first support bars, through an actuation of the at least one third adjusting set, a moving direction of the odd-sequenced first support bars along the X-axis direction is opposite to a moving direction of the even-sequenced first support bars along the X-axis direction,
the second support bars are arranged across the first support bars, the second support bars are disposed along the Y-axis direction in the at least one fourth adjusting set, the second support bars comprise a plurality of odd-sequenced second support bars and a plurality of even-sequenced second support bars, through an actuation of the at least one fourth adjusting set, a moving direction of the odd-sequenced second support bars along the Y-axis direction is opposite to a moving direction of the even-sequenced second support bars along the Y-axis direction, and
the support pillars are disposed at locations where the first support bars and the second support bars cross each other.

12. The device interface according to claim 11, wherein at the locations where the first support bars and the second support bars cross each other, each of the first support bars has a first groove along a length direction of the first support bar and each of the second support bars has a second groove along a length direction of the second support bar, the first grooves and the second grooves cross each other orthogonally, and each of the support pillars is disposed at one of the locations where the first grooves and the second grooves overlap.

13. The device interface according to claim 12, wherein the support pillars slide along the second grooves when the odd-sequenced first support bars and the even-sequenced first support bars move along the X-axis direction, and the support pillars slide along the first grooves when the odd-sequenced second support bars and the even-sequenced second support bars move along the Y-axis direction.

14. The device interface according to claim 13, wherein viewing along one of the second support bars, the support pillars comprise the first support pillar to the 2m-th support pillar arranged sequentially along the X-axis direction, where m is a positive integer, and a distance between the (2n-1)-th support pillar and the 2n-th support pillar is corresponding to a length of each chip test socket in the X-axis direction, where n is a positive integer and n is less than or equal to m.

15. The device interface according to claim 14, wherein viewing along one of the first support bars, the support pillars comprise the first support pillar to the 2p-th support pillar arranged sequentially along the Y-axis direction, where p is a positive integer, and a distance between the (2q-1)-th support pillar and the 2q-th support pillar is corresponding to a width of each chip test socket in the Y-axis direction, where q is a positive integer and q is less than or equal to p.

16. The device interface according to claim 15 further comprises a plurality of support bases, wherein each of the support bases comprises a main body and a plurality of protruding platform sections, the main body comprises a first surface and a second surface opposite to the first surface, the protruding platform sections are formed on the first surface, and each of the support bases is jointly supported on the four corners by the (2q-1)-th support pillars and the 2q-th support pillars on the two adjacent first support bars, or by the (2n-1)-th support pillars and the 2n-th support pillars on the two adjacent second support bars.

17. The device interface according to claim 16, wherein each of the support pillars comprises a slot, and each of the support bases comprises four insert sections which are inserted into the slots of the support pillars on the four corners of the support base.

18. The device interface according to claim 11, wherein the at least one third adjusting set comprises two third gear racks and a third pinion, the third gear racks are parallel to each other in the length direction and extend along the X-axis direction, the third pinion is engaged between the third gear racks, the third gear racks are adapted to move correspondingly on opposite sides of a radial direction of the third pinion, the odd-sequenced first support bars are fixed on one of the third gear racks, and the even-sequenced first support bars are fixed on the other of the third gear racks.

19. The device interface according to claim 18, wherein the third gear racks comprise a plurality of first install holes along the length direction, and each of the first support bars is fixedly installed in one of the first install holes.

20. The device interface according to claim 18, wherein a quantity of the at least one third adjusting set is two, the two third adjusting sets are disposed separately, the third pinions of the two third adjusting sets are rotated synchronously, the odd-sequenced first support bars are fixed on the two third gear racks of the two third adjusting sets which move in the same direction, the even-sequenced first support bars are fixed on the other two third gear racks of the two third adjusting sets which move in the same direction.

21. The device interface according claim 18, wherein the at least one fourth adjusting set comprises two fourth gear racks and a fourth pinion, the two fourth gear racks are parallel to each other in the length direction and extend along the Y-axis direction, the fourth pinion is engaged between the two fourth gear racks, the fourth gear racks are adapted to move correspondingly on opposite sides of a radial direction of the fourth pinion, the odd-sequenced second support bars are fixed on one of the fourth gear racks, and the even-sequenced second support bars are fixed on the other of the fourth gear racks.

22. The device interface according to claim 21, wherein the fourth gear racks comprise a plurality of second install holes along the length direction, and each of the second support bars is fixedly installed in one of the second install holes.

23. The device interface according to claim 21, wherein a quantity of the at least one fourth adjusting set is two, the two fourth adjusting sets are disposed separately, the fourth pinions of the two fourth adjusting sets are rotated synchronously, the odd-sequenced second support bars are fixed on the two fourth gear racks of the two fourth adjusting sets which move in the same direction, and the even-sequenced second support bars are fixed on the other two fourth gear racks of the two fourth adjusting sets which move in the same direction.

24. The device interface according to claim 21 further comprises a bearing platform, wherein the at least one third adjusting set further comprises a third motor, the at least one fourth adjusting set further comprises a fourth motor, the bearing platform is disposed in the spacing, the third pinion and the fourth pinion are disposed on one side of the bearing platform facing the performance board, the third motor and the fourth motor are disposed on one side of the bearing platform facing the test head, a drive shaft of the third motor passes through the bearing platform and is connected to the third pinion to control the third pinion's actuation, and a drive shaft of the fourth motor passes through the bearing platform and is connected to the fourth pinion to control the fourth pinion's actuation.

25. A method of adjusting the device interface according to claim 13, wherein the method comprises:
adjusting the two first frames to move toward or away from each other along the Y-axis direction for bearing the performance board through the two first frames;
adjusting the two second frames to move toward or away from each other along the Y-axis direction for corresponding to the probe modules of the test head;
adjusting the odd-sequenced first support bars and the even-sequenced first support bars to move along the X-axis direction to make the support pillars slide along the second grooves; and
adjusting the odd-sequenced second support bars and the even-sequenced second support bars to move along the Y-axis direction to make the support pillars slide along the first grooves;
wherein viewing along one of the second support bars, the support pillars comprise the first support pillar to the 2m-th support pillar arranged sequentially along the X-axis direction, where m is a positive integer, a distance between the (2n-1)-th support pillar and the 2n-th support pillar is corresponding to a length of each chip test socket in the X-axis direction, where n is a positive integer and n is less than or equal to m; and
wherein viewing along one of the first support bars, the support pillars comprise the first support pillar to the 2p-th support pillar arranged sequentially along the Y-axis direction, where p is a positive integer, and a distance between the (2q-1)-th support pillar and the 2q-th support pillar is corresponding to a width of each chip test socket in the Y-axis direction, where q is a positive integer and q is less than or equal to p.
